(19) United States
(12) Patent Application Publication
(10) Pub. No.: US 2014/0198593 A1
(43) Pub. Date: Jul. 17, 2014

(54) REDUNDANCY CIRCUIT AND SEMICONDUCTOR MEMORY DEVICE INCLUDING THE SAME

(71) Applicant: SAMSUNG ELECTRONICS CO., LTD., Suwon-si (KR)

(72) Inventors: Sang-Hyuk KWON, Seoul (KR); In-Chul JEONG, Suwon-si (KR)

(73) Assignee: SAMSUNG ELECTRONICS CO., LTD., Suwon-si (KR)

(21) Appl. No.: 14/158,067

(22) Filed: Jan. 17, 2014

(30) Foreign Application Priority Data
Jan. 17, 2013 (KR) 10-2013-0005541

(51) Int. Cl. G11C 29/04

(52) U.S. Cl. CPC G11C 29/04
USPC 365/200

(57) ABSTRACT

A redundancy circuit includes a redundancy decoder, a fuse array, and a decoder. The redundancy decoder decodes a redundancy enable signal generated when an address of a defective cell matches an input address. The decoded redundancy enable signal is used to activate a spare column select line connected with a redundancy block to be substituted for the defective cell designated by the defective cell address. The fuse array includes fuse elements to designate segments in the redundancy block based on availability of the segments. The decoder decodes coding signals from the fuse array to connect at least one of the fuse elements with the spare column select line.

### CROSS-REFERENCE TO RELATED APPLICATION

Korean Patent Application No. 10-2013-0005541, filed on Jan. 17, 2013, and entitled “Redundancy Circuit and Semiconductor Memory Device Including the Same,” is incorporated by reference herein in its entirety.

### BACKGROUND

1. Field

One or more embodiments herein relate a semiconductor memory device.

2. Description of the Related Art

During the manufacturing process of a semiconductor memory, a variety of defects may occur on a chip. For example, fine dust and/or other particulates may become attached to the surface of a wafer, or a slurry may be biased onto the wafer surface during polishing. When defects occur on a chip, only a memory cell having the defect may fail. Other memory cells may normally operate under these circumstances. However, even when a defect occurs to only a few memory cells, the whole chip is regarded as a defective product.

Several approaches have been proposed for addressing this problem. One approach involves using a redundancy memory cell on the chip. In this case, if read-out data and write data stored in the defective memory cell are substituted with data stored in the redundancy memory cell, the product yield may be improved.

As memory capacity increases, address information corresponding to the memory is also expected to increase. Consequently, the capacity of an on-chip redundancy memory will also increase, which, in turn, will increase the number of fuses having defective addresses due to the capacity of the redundancy memory. Further, the number of fuses is also increased in order to increase redundancy resources.

### SUMMARY

In accordance with one embodiment, a redundancy circuit includes a redundancy decoder configured to decode a redundancy enable signal generated when an address of a defective cell matches an input address, the decoded redundancy enable signal to activate a spare column select line connected with a redundancy block to be substituted for the defective cell designated by the defective cell address; a fuse array including a plurality of fuse elements to designate a plurality of segments in the redundancy block based on availability of the segments; and a decoder configured to decode a plurality of coding signals provided from the fuse array and to connect at least one of the fuse elements with the spare column select line.

Also, the fuse array may provide the coding signals to the decoder in response to the redundancy enable signal. The fuse array may include a plurality of transistors connected with the fuse elements, respectively, to provide coding information of the fuse elements to the decoder as the coding signals in response to the redundancy enable signal.

Also, each of the fuse elements may include an anti-fuse element. The anti-fuse element may output a high-level coding signal when the anti-fuse element is programmed, and outputs a low-level coding signal when the anti-fuse element is not programmed.

Also, each of the fuse elements may include an electrical fuse element. The electrical fuse element may output a low-level coding signal when the electrical fuse element is programmed, and outputs a high-level coding signal when the electrical fuse element is not programmed.

Also, all fuse elements except for at least one fuse element may be used to designate corresponding ones of the segments, and the at least one fuse element may be indicative of a designation state of a segment adjacent to one of the segments designated by remaining ones of the fuse elements.

Also, all fuse elements except for at least first and second fuse elements may designate corresponding segments, the first fuse element may represent an availability state of one segment designated by the remaining ones of the fuse elements, and the second fuse element may represent a designation state of a segment adjacent to the one segment designated by the remaining ones of the fuse elements.

Also, the redundancy decoder may deactivate a normal column decoder to access the defective cell designated by the input address, in response to the redundancy enable signal.

Also, the decoder may include a decoding unit to decode the coding signals to provide a plurality of select signals; and a switching unit comprising a plurality of switches to selectively connect the segments with the spare column select line in response to the select signals.

In accordance with another embodiment, a semiconductor memory device includes a memory cell array including normal memory cell blocks and redundancy cell blocks corresponding to the normal memory cell blocks; a normal decoder configured to access the normal memory cell blocks in response to an input address; and a redundancy circuit configured to substitute a defective cell, in at least one of the normal memory cell blocks, with a segment of the redundancy cell blocks.

The redundancy circuit includes a redundancy decoder configured to decode a redundancy enable signal generated when an address of a defective cell matches an input address, the decoded redundancy enable signal to activate a spare column select line connected with a redundancy block to be substituted for the defective cell designated by the defective cell address; a fuse array including a plurality of fuse elements to designate a plurality of segments in the redundancy block based on availability of the segments; and a decoder configured to decode a plurality of coding signals provided from the fuse array and to connect at least one of the fuse elements with the spare column select line.

Also, the redundancy decoder may deactivate the normal decoder in response to the redundancy enable signal, and the fuse array may include a plurality of transistors connected with the fuse elements, respectively, to provide coding information of the fuse elements to the decoder as the coding signals in response to the redundancy enable signal.

Also, all fuse elements except for at least one fuse element may designate corresponding ones of the segments, and the at least one fuse element may be indicative of a designation state of a segment adjacent to one segment designated by remaining ones of the fuse elements.

Also, the redundancy block may be selected by a portion of bits of a row address constituting the input address to access the memory cell array.

Also, a fuse circuit may be configured to selectively activate the redundancy enable signal based on a match between the address of the defective cell and the input address.

In accordance with another embodiment, a controller includes a first circuit to receive a signal indicative of a defective cell in a first array of memory locations, the defective cell included in a sub-block of the first array of memory locations; and a second circuit to generate a signal to substitute the defective cell in the sub-block of the first array of the memory locations with a segment in a second array of memory locations, the segment in the second array of memory locations included in a sub-block of the second array of memory locations, wherein cells in the sub-block of the first array of memory locations except the defective cell and the segment in the second array of memory locations form a single storage location for storing different bits of data.

Also, the defective cell in the sub-block of the first array of memory locations and the segment in the second array of memory locations may have a same size. The sub-block in the second array of memory locations may include a plurality of segments in one-to-one correspondence with cells in the sub-block of the first array of memory locations.

Also, the second circuit is to generate the signal to substitute the defective cell in the sub-block of the first array of memory locations with the segment in the sub-block of the second array of memory locations based on availability states of the segments in the sub-block of the second array of memory locations.

### BRIEF DESCRIPTION OF THE DRAWINGS

Features will become apparent to those of ordinary skill in the art by describing in detail exemplary embodiments with reference to the attached drawings in which:

FIG. 1 illustrates an embodiment of a semiconductor memory device;

FIG. 2 illustrates an example of a fuse circuit in FIG. 1;

FIG. 3 illustrates an example of one of a plurality of fuse sets in FIG. 2;

FIG. 4 illustrates an example of an address comparator in FIG. 2;

FIG. 5 illustrates a portion of the semiconductor memory device in FIG. 1;

FIG. 6 illustrates an example of how a defective memory cell in FIG. 5 may be substituted with a segment of a sub-redundancy block;

FIG. 7 illustrates an example of a fuse array in FIG. 6;

FIG. 8 illustrates an example of the coding of anti-fuse elements when the fuse array of FIG. 6 is configured as illustrated in FIG. 7;

FIG. 9 illustrates another example of the fuse array in FIG. 6;

FIG. 10 illustrates another example of the fuse array in FIG. 6;

FIG. 11 illustrates an example of the coding of anti-fuse elements when the fuse array of FIG. 6 is configured as in FIG. 10;

FIG. 12 illustrates another example of the fuse array in FIG. 6;

FIG. 13 illustrates an example of the coding of anti-fuse elements when the fuse array of FIG. 6 is configured as in FIG. 12;

FIG. 14 illustrates an example of the decoder in FIG. 6;

FIG. 15 illustrates an embodiment of a repair method for a semiconductor memory device;

FIG. 16 illustrates an embodiment of a memory system;

FIG. 17 illustrates an embodiment of a memory module;

FIG. 18 illustrates an embodiment of a mobile system; and

FIG. 19 illustrates an embodiment of a computing system.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

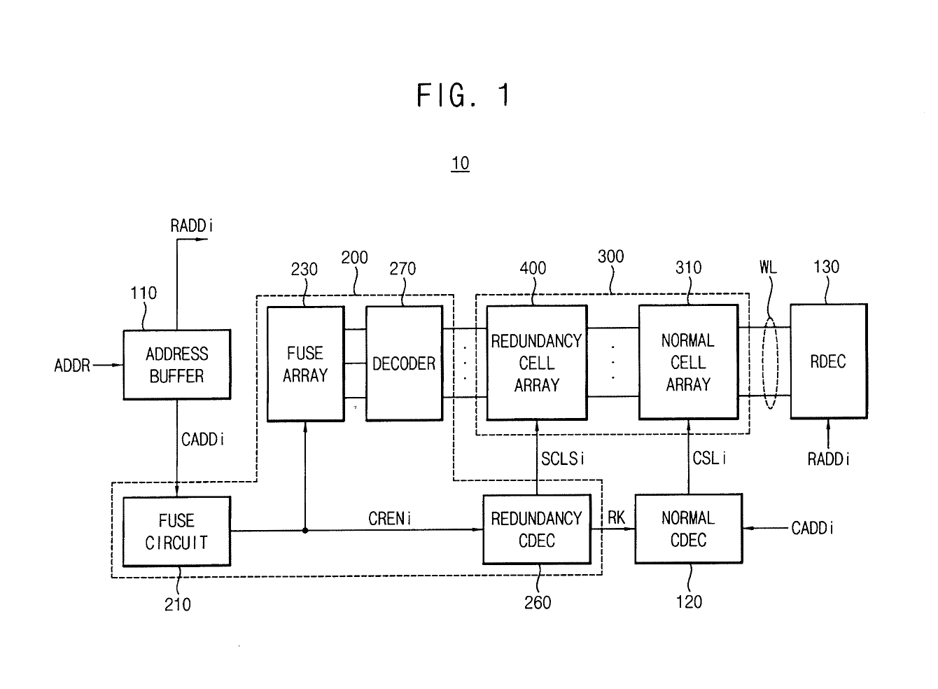

FIG. 1 illustrates an embodiment of a semiconductor memory device 10 which includes an address buffer 110, a normal decoder 120, a row decoder 130, a redundancy circuit 200, and a memory cell array 300. The redundancy control circuit may be considered to be included in a controller formed alone or with one or more other elements shown in the embodiments described herein.

The redundancy circuit 200 may include a fuse circuit 210, a fuse array 230, a redundancy column decoder 260, and a decoder 270. The memory cell array 300 (also referred to as “memory location”) may include a normal cell array (also referred to as a first array) 310 and a redundancy cell array (also referred to as a second array) 400.

The address buffer 110 receives an external address ADDR provided from an external device, and buffers the external address ADDR. The address buffer 110 provides a column address CADDi of the external address ADDR to both of the redundancy circuit 200 and the normal decoder 120, and provides a row address RADDi of the external address AADR to the row decoder 130.

In the case of accessing a normal cell instead of a defective cell, the column address CADDi is decoded by the normal decoder 120 and the row address RADDi is decoded by the row address decoder 120, thereby performing an access procedure to a cell in the normal cell array 310.

However, in the case of accessing a defective cell in the normal cell array 310, a defective cell stored in the fuse circuit 210 must be substituted with a segment of the redundancy cell array 400. If the column address CADDi is matched with a redundancy address, which is the address of the defective cell stored in the fuse circuit 210, a redundancy enable signal CRENi is activated, in order to activate the redundancy decoder (the redundancy column decoder 260). The activated redundancy column decoder 260 disables the normal decoder 120 using an output signal RK, and the defective cell is substituted with one or more segments of a related redundancy block in the redundancy cell array 400.

When the defective cell is substituted with one or more segments of the related redundancy block in the redundancy cell array 400, one segment to be substituted may be selected by decoding coding signals by the decoder 270. The decoding signals may be output from the fuse array 230, including a plurality of fuse elements, to designate the segments based on the availability of the segments of the redundancy block.

The memory cell array 300 is connected with the row decoder 130 through a plurality of word lines WL. The normal decoder 120 is connected with the normal cell array 310 through a plurality of column select lines CSLi. The redundancy cell array 400 is connected with the redundancy column decoder 260 through a plurality of spare column select lines SCSLi. The column select lines CSLi correspond to a plurality of bit lines, and normal cells are formed at regions where the bit lines cross the word lines WL. The spare column select lines SCSLi correspond to a plurality of redundancy bit lines, and redundancy cells are formed at regions where the redundancy bit lines cross the word lines WL.

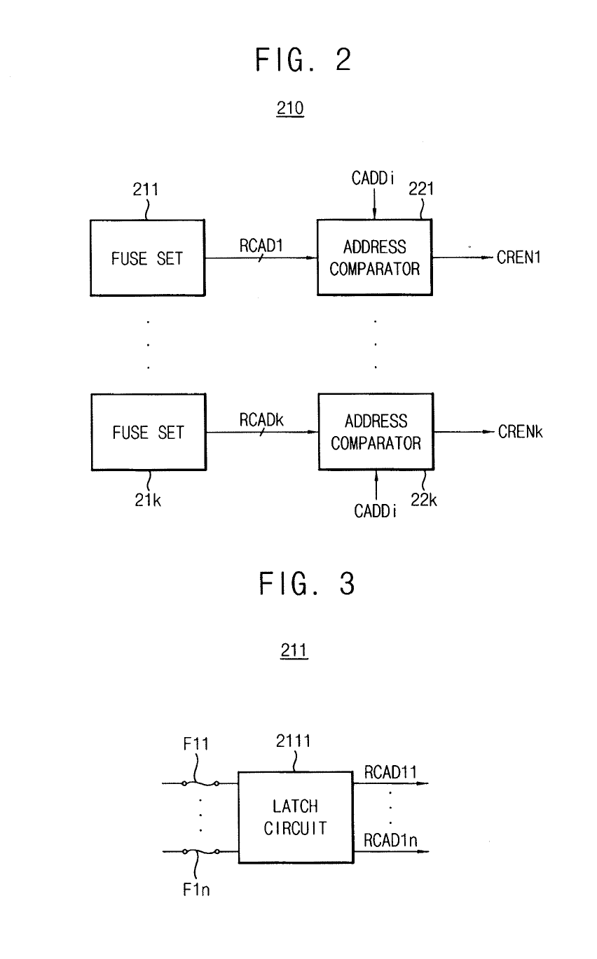

FIG. 2 illustrates an example of the fuse circuit 210 in FIG. 1. Referring to FIG. 2, the fuse circuit 210 may include a plurality of fuse sets 211 to 21k (k is an integer equal to or greater than 2) and a plurality of address comparators 221 to 22k. The fuse sets 211 to 21k store and output redundancy addresses RCAD1 to RCADk which are addresses of defective cells tested and programmed in a wafer level or a package level, respectively. The address comparators 221 to 22k compare the column address CADDi, which is currently input, with each of the redundancy addresses RCAD1 to RCADk in the unit of a bit. Based on this comparison, the address comparators output redundancy enable signals CREN1 to CRENk, which are selectively activated if the column address CADDi matches the redundancy addresses RCAD1 to RCADk. Each of the fuse sets 211 to 21k may include a plurality of fuse elements to store bits of each of the redundancy addresses RCAD1 to RCADk, respectively.

FIG. 3 illustrates an example of one of the fuse sets in FIG. 2. Referring to FIG. 3, the fuse set 211 may include a plurality of fuses F11 to F1n to store the information of defective addresses and a latch circuit 2111 to store the states of the fuses F11 to F1n. The latch circuit 2111 may output the program states of the fuses F11 to F1n to the bits RCAD11 to RCAD1n, respectively. Although FIG. 3 illustrates a configuration of fuse set 211 among the fuse sets 211 to 21k of FIG. 2, other fuse sets 212 to 21k may have configurations substantially identical to that of the fuse set 211.

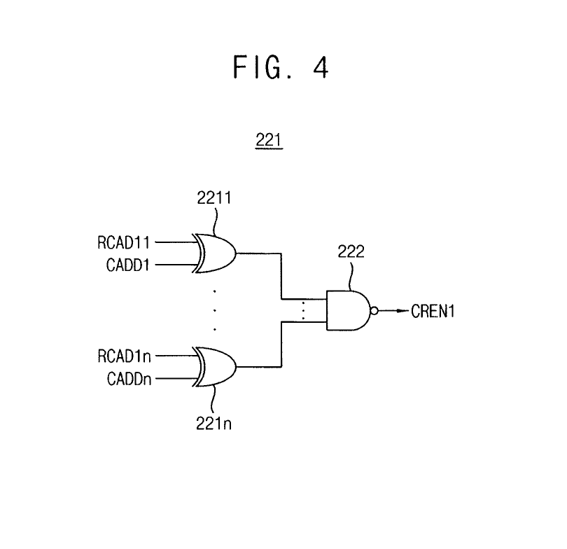

FIG. 4 illustrates an example of one of the address comparators 221 to 22k of FIG. 2. Referring to FIG. 4, the address comparator 221 may include a plurality of XOR gates 2211 to 221n and a NAND gate 222. Each of the XOR gates 2211 to 221n receives each of bits RCAD11 to RCAD1n of the redundancy address and each of bits CADD1 to CADDn of the column address. In other words, each of the XOR gates 2211 to 221n determines the matching state between each of the bits RCAD11 to RCAD1n of the redundancy address and each of the bits CADD1 to CADDn of the column address. Each XOR gate outputs a low level signal if the two inputs are matched with each other, and outputs a high level signal if the two inputs are different from each other.

Accordingly, all XOR gates 2211 to 221n output low level signals if all bits RCAD11 to RCAD1n of the redundancy address match all bits CADD1 to CADDn of the column address. In this case, the NAND gate 222 may output a high-level redundancy enable signal CREN1. If the bits RCAD11 to RCAD1n of the redundancy address are different from at least one of the bits CADD1 to CADDn of the column address, at least one of the outputs of the XOR gates 2211 to 221n is at a high level, so that the NAND gate 222 may output a low level redundancy enable signal CREN1.

Although FIG. 4 illustrates the configuration of the address comparator 221 among the address comparators 221 to 22k of FIG. 2, the remaining address comparators 222 to 22k may have the configuration substantially identically to that of the address comparator 221. Also, in FIG. 4, a plurality of XNOR gates may be employed instead of the XOR gates 2211 to 221n, and an AND gate may be employed instead of the NAND gate 222.

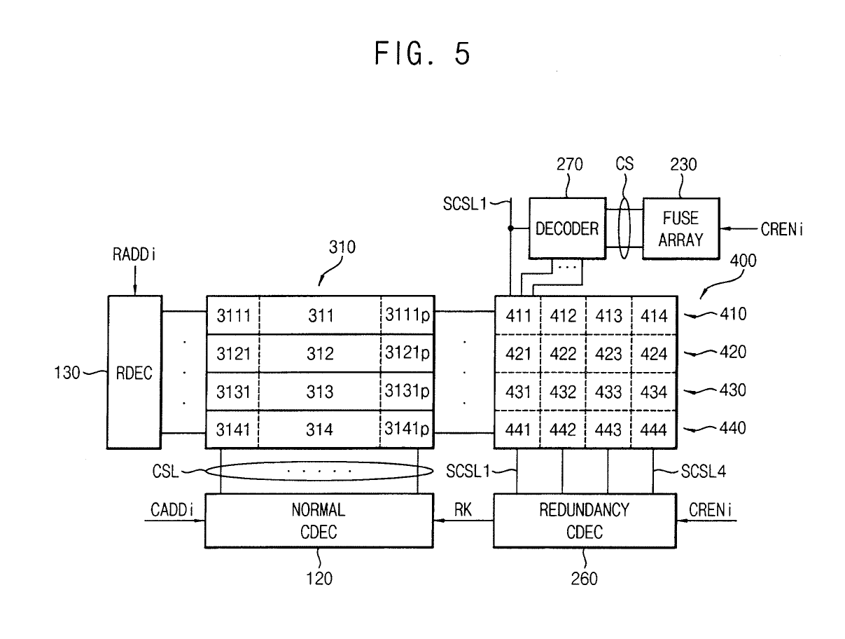

FIG. 5 illustrates an example of a semiconductor memory device 300 illustrated in FIG. 1. Referring to FIG. 5, the normal cell array 310 may include a plurality of memory blocks 311, 312, 313, and 314. The redundancy cell array 400 may include redundancy blocks 410,420, 430, and 440 corresponding to the memory blocks 311, 312, 313, and 314, respectively. Each of the redundancy blocks 410, 420, 430, and 440 is connected with a corresponding one of the memory blocks 311, 312, 313, and 314 through the same word line.

The memory block 311 may include a plurality of sub-blocks 3111 to 311p. The memory block 312 may include a plurality of sub-blocks 3121 to 312p. The memory block 313 may include a plurality of sub-blocks 3131 to 313p. The memory block 314 may include a plurality of sub-blocks 3141 to 314p. In this case, the sub-blocks 3111, 3121, 3131, and 3141 may be connected with the same column select line CSL. In other words, the sub-blocks 3111, 3121, 3131, and 3141 may constitute at least one column of the normal cell array 310.

Similarly, the redundancy block 410 may include a plurality of sub-redundancy blocks 411, 412, 413, and 414. The redundancy block 420 may include a plurality of sub-redundancy blocks 421, 422, 423, and 424. The redundancy block 430 may include a plurality of sub-redundancy blocks 431, 432, 433, and 434. The redundancy block 440 may include a plurality of sub-redundancy blocks 441, 442, 443, and 444. The sub-redundancy blocks 411, 421, 431, and 441 may be connected with a spare column select line SCSL1. In other words, the sub-redundancy blocks 411, 421, 431, and 441 may constitute one redundancy column.

The sub-redundancy blocks 412, 422, 432, and 442 may be connected with a spare column select line SCSL2. The sub-redundancy blocks 413, 423, 433, and 443 may be connected with a spare column select line SCSL3. The sub-redundancy blocks 414, 424, 434, and 444 may be connected with a spare column select line SCSL4.

According to one type of a redundancy scheme, if sub-memory block 3111 includes a defective cell, the sub-memory block 3111 is substituted with the redundancy sub-memory block 411. Accordingly, if at least one redundancy cell in the sub-memory block 3111 is defective, the whole sub-memory block 3111 cannot be used. This represents an inefficient use of redundancy resource.

However, in accordance with at least one embodiment, a semiconductor memory device is coupled to the fuse array 230 and the decoder 270. Thus, for example, when the sub-memory block 3111 includes at least one defective cell (e.g., cell 3111b out of cells 3111a to 3111L) and is substituted with a segment (or a redundancy cell) in the sub-redundancy block 411, at least one segment of the sub-redundancy block 411 may be defective. In this case, the fuse array 230 is provided to include fuse elements to designate the segments of the sub-redundancy block 411 based on the availability of each segment of the sub-redundancy block 411. The fuse array 230 may output a coding signal CS in response to the redundancy enable signal CRENi. The decoder 270 may connect one of available segments of the sub-redundancy block 411, which are substituted for the defective cell of the sub-memory block 3111, with the spare column select line SCSL1 by decoding the coding signal CS provided from the fuse array 400.

In addition, the number of the fuse elements in the fuse array 230 may be sufficient if the fuse elements included in the fuse array 230 enable the coding of the segments constituting the sub-redundancy block 411, so the increase of the fuse elements can be minimized. For example, when one sub-redundancy block is partitioned into 2̂q segments, it is sufficient if the number of fuse elements included in the fuse array 230 is at least q. Accordingly, the increase of the fuse elements can be minimized while significantly increasing the number of available redundancy resources.

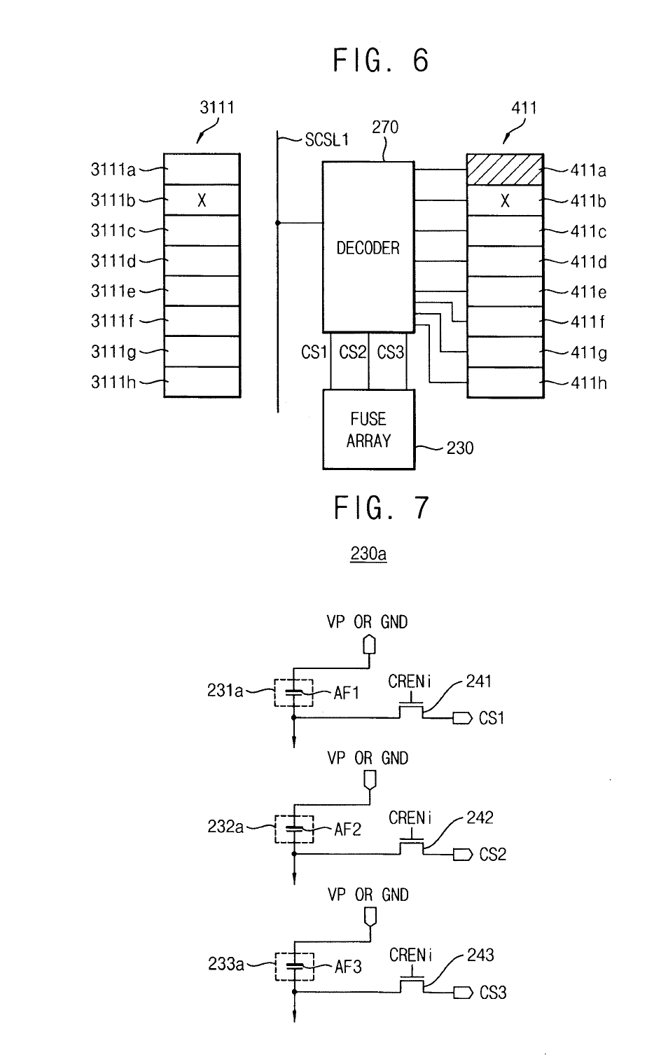

FIG. 6 illustrates an example of an operation which may be performed when a defective memory cell in the semiconductor memory device of FIG. 5 is substituted with a segment of the sub-redundancy block.

Referring to FIGS. 1 to 6, the sub-memory block 3111 includes memory cells 3111a to 3111f. Among them, the memory cell 3111b is a defective cell, as shown by symbol X. The address of the memory cell 3111b is programmed in one of the fuse sets 211 to 21k of FIG. 2 in the form of a redundancy address. If the column address CADDi is input in order to access the memory cell 3111b, one of the redundancy enable signals CREN1 to CRENk is enabled in FIG. 2. In this case, it is assumed that the redundancy enable signal CREN1 is activated. Since the redundancy enable signal CREN1 is activated, the column redundancy decoder 260 outputs the output signal RK to disable the normal decoder 120, and activates the spare column select line SCSL1 connected with the redundancy memory block 411 corresponding to the sub-memory block 3111, by decoding the redundancy enable signal CREN1.

In this case, the fuse array 230 provides the coding signals CS1, CS2, and CS3, which dedicate one of segments 411a, and 411c to 411f, which are available among the segments 411a to 411h of the sub-redundancy block 411, to the decoder 270 in response to the redundancy enable signal CREN1. In this case, it is assumed that the segment 411a among the available segments 411a and 411c to 411f is substituted for the defective cell 3111b. In this case, the coding signals CS1, CS2, and CS3 may be “000”. If the fuse elements included in the fuse array 230 are anti-fuse elements, the coding signals CS1, CS2, and CS3 of “000” may be output. In addition, if the fuse elements included in the fuse array 230 are electric fuse elements, and if all electric fuse elements are programmed, the coding signals CS1, CS2, and CS3 of “000” may be output.

The decoder 270 decodes the coding signals CS1, CS2, and CS3 of “000” to link a connection line, which is connected with the segment 411a, among a plurality of connection lines 280, with the spare column select line SCSL1. Accordingly, the defective cell 3111b may be substituted with the segment 411a. Since the segment 411a corresponds to the defective cell, the fuse elements included in the fuse array 230 may be coded such that the segment 411b is not used.

FIG. 7 illustrates an example of a fuse array 230a of FIG. 6. Referring to FIG. 7, fuse array 230 may include a plurality of fuse cells 231a, 232a, and 233a, and a plurality of transistors 241, 242, and 243.

The fuse cells 231a, 232a, and 233a may include anti-fuse elements AF1, AF2, and AF3, respectively. Each of the anti-fuse elements AF1, AF2, and AF3 has a first terminal connected with program voltage VP or ground voltage GND, and a second terminal connected with the ground voltage GND. Each of the anti-fuse elements AF1, AF2, and AF3 may be individually programmed by the program voltage VP or the ground voltage GND applied to the first terminal thereof. Each of the transistors 241, 242, and 43 may include a first electrode connected with the first terminal of each of the anti-fuse elements AF1, AF2, and AF3, a gate to receive the redundancy enable signal CERNi, and a second electrode to provide each of the coding signals CS1, CS2, and CS3.

Accordingly, if the anti-fuse elements AF1, AF2, and AF3 are selectively programmed based on the available states of segments 411a to 411h constituting the sub-redundancy block 411, the coding signals CS1, CS2, and CS3 may have a corresponding logic level corresponding.

For example, as described with reference to FIG. 6, when the defective cell 3111b is substituted with the segment 411a, the ground voltage GND is applied to the first terminals of the anti-fuse elements AF1, AF2, and AF3, so that the anti-fuse elements AF1, AF2, and AF3 may not be programmed. In this case, the coding signals CS1, CS2, and CS3 may have the logic level of “000”, and the decoder 270 may connect the segment 411a with the spare column select line SCSL1 in response to the coding signals CS1, CS2, and CS3 of “000.”

Alternatively, when the defective cell 3111b is substituted with the segment 411c, the anti-fuse elements AF1 and AF3 may not be programmed, but the anti-fuse element AF2 may be programmed. In this case, the coding signals CS1, CS2, and CS3 may have the logic level of “010”, and the decoder 270 may connect the segment 411c with the spare column select line SCSL1 in response to the coding signals CS1, CS2, and CS3 of “010”.

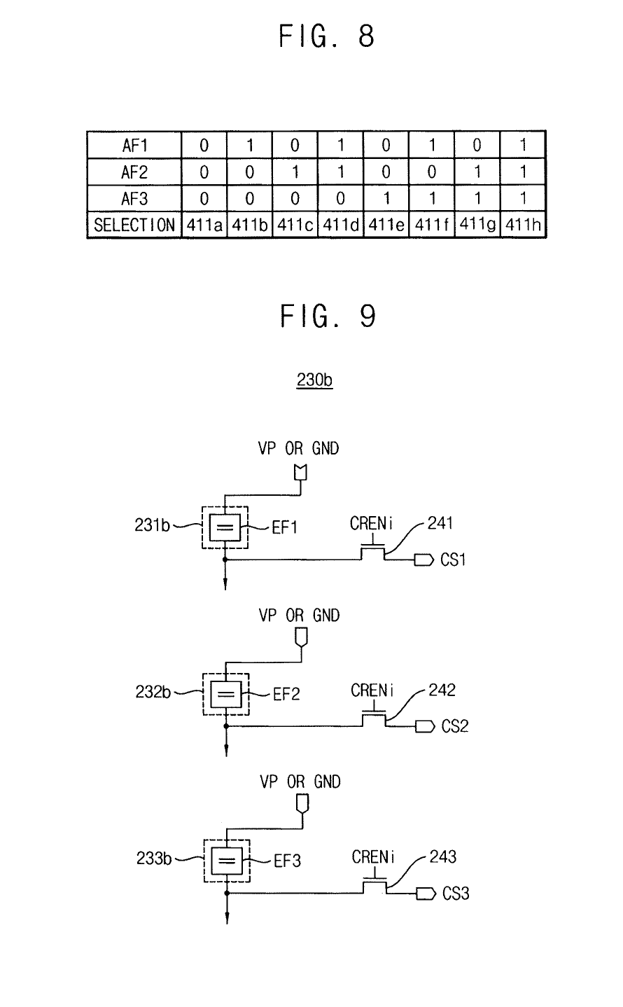

FIG. 8 illustrates an example of coding of the anti-fuse elements when the fuse array of FIG. 6 is configured as illustrated in FIG. 7. Referring to FIGS. 7 and 8, the anti-fuse elements AF1, AF2, and AF3 may be coded to output the coding signals CS1, CS2, and CS3 having one of logic levels of “000”, “100”, “010”, “110”, “001”, “101”, “011”, and “111” according to program states.

If the coding signals CS1, CS2, and CS3 have each of the logic levels of “000”, “100”, “010”, “110”, “001”, “101”, “011” and “111”, each of the segments 411a, 411b, 411c, 411d, 411e, 411f, 411g, and 411h may be connected with the spare column select line SCSL1 corresponding to the logic level of the coding signals CS1, CS2, and CS3. However, since the segment 411b is defective according to the example of FIG. 6, the segment 411b is not connected with the spare column select line SCSL1.

FIG. 9 illustrates another example of the fuse array 230b of FIG. 6. Referring to FIG. 9, a fuse array 230b may include a plurality of fuse cells 231b, 232b, and 233b, and a plurality of transistors 241, 242, and 243.

The fuse cells 231b, 232b, and 233b may include electrical fuse elements EF1, EF2, and EF3, respectively. Each of the electrical fuse elements EF1, EF2, and EF3 has a first terminal connected with program voltage VP or ground voltage GND, and a second terminal connected with the ground voltage GND. Each of the electrical fuse elements EF1, EF2, and EF3 may be individually programmed by the program voltage VP or the ground voltage GND applied to the first terminal thereof. Each of the transistors 241, 242, and 43 may include a first electrode connected with the first terminal of each of the electrical fuse elements EF1, EF2, and EF3, a gate to receive the redundancy enable signal CERNi, and a second electrode to provide each of the coding signals CS1, CS2, and CS3.

Accordingly, if the electrical fuse elements EF1, EF2, and EF3 are selectively programmed based on the available states of segments 411a to 411h constituting the sub-redundancy block 411, the coding signals CS1, CS2, and CS3 may have a corresponding logic level. For example, as described with reference to FIG. 6, when the defective cell 3111b is substituted with the segment 411a, the program voltage VP is applied to the first terminals of the electrical fuse elements EF1, EF2, and EF3, so that the electrical fuse elements EF1, EF2, and EF3 may be programmed. In this case, the coding signals CS1, CS2, and CS3 may have the logic level of “000”, and the decoder 270 may connect the segment 411a with the spare column select line SCSL1 in response to the coding signals CS1, CS2, and CS3 of “000.”

For example, when the defective cell 3111b is substituted with the segment 411a, the electrical fuse elements EF1 and EF3 may be programmed, but the electrical fuse element EF2 may not be programmed. In this case, the coding signals CS1, CS2, and CS3 may have the logic level of “010,” and the decoder 270 may connect the segment 411c with the spare column select line SCSL1 in response to the coding signals CS1, CS2, and CS3 of “010”.

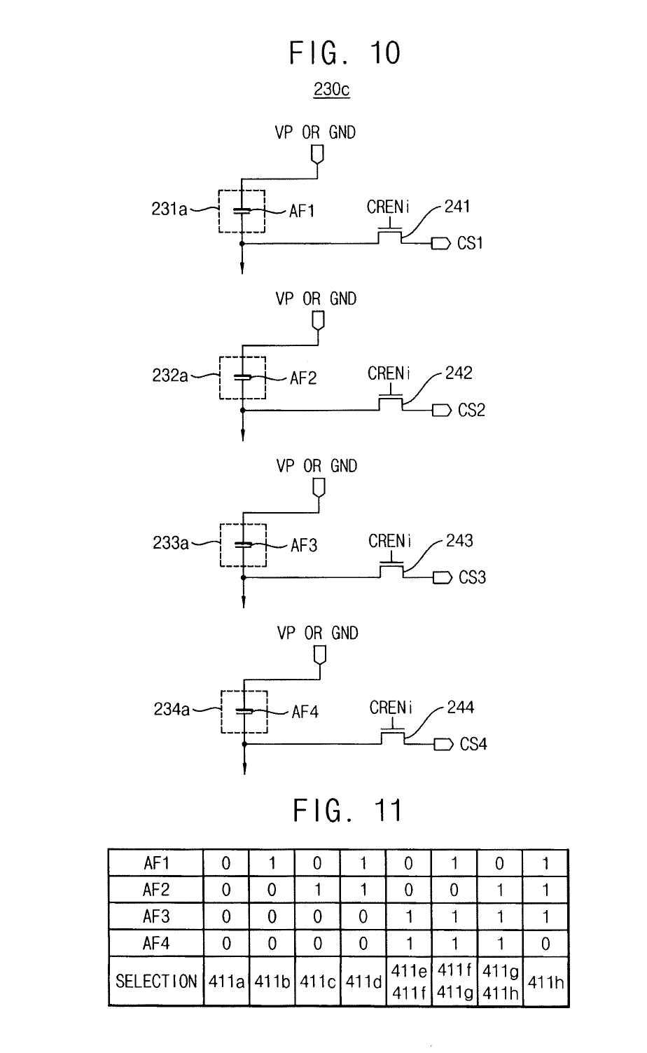

FIG. 10 illustrates another example of the fuse array 230c of FIG. 6. Referring to FIG. 10, a fuse array 230c may include a plurality of fuse cells 231a, 232a, 233a, and 234a, and a plurality of transistors 241, 242, 243, and 244.

The fuse array 230c of FIG. 10 is different from the fuse array 230a of FIG. 7, in that the fuse array 230c further includes the fuse cell 234a including an anti-fuse element AF4 and a transistor 244. The anti-fuse element A4 may be coded according to the designation state of a segment adjacent to a segment designated through the coding of the anti-fuse elements AF1, AF2, and AF3.

For example, when the anti-fuse elements AF1 and AF3 are not programmed, and the anti-fuse element AF2 designates a segment 411c, the anti-fuse element AF4 is assumed as being programmed. In this case, the segment 411c and a segment 411d adjacent to the segment 411c may be simultaneously designated by the coding of the anti-fuse elements AF1 to AF4. In addition, the decoder 270 may connect the segments 411c and 411d with the spare column select line SCSL1 in response to coding signals CS1, CS2, CS3, and CS4 of “0101.”

FIG. 11 illustrates another example of coding the anti-fuse elements when the fuse array of FIG. 6 is configured as illustrated in FIG. 10. Referring to FIGS. 10 and 11, the anti-fuse elements AF1, AF2, and AF3 may be coded to output the coding signals CS1, CS2, and CS3 having one of logic levels of “000”, “100”, “110”, “010”, “001”, “101”, “011”, and “111” according to program states.

The anti-fuse element A4 may be coded to have a logic level of “0” or “1” according to the designation state of a segment adjacent to a segment designated through the coding of the anti-fuse elements AF1, AF2, and AF3. For example, if the anti-fuse elements AF1, AF2, AF3, and AF4 are coded to output the coding signals CS1 to CS4 of “1100,” only the segment 411d is connected with the spare column select line SCSL1. For example, if the anti-fuse elements AF1, AF2, AF3, and AF4 are coded to have the coding signals CS1 to CS4 of “1011,” a segment 411f and a segment 411g adjacent thereto may be connected with the spare column select line SCSL1.

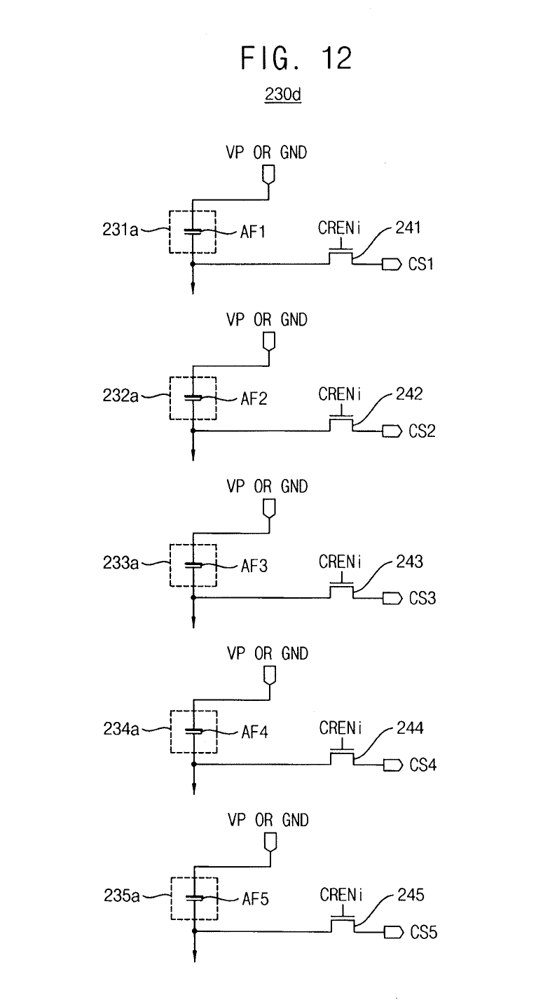

FIG. 12 illustrates another example of the fuse array 230d of FIG. 6. Referring to FIG. 12, a fuse array 230d may include a plurality of fuse cells 231a, 232a, 233a, 234a, and 235a, and a plurality of transistors 241, 242, 243, 244, and 245.

The fuse array 230d of FIG. 12 is different from the fuse array 230c of FIG. 10, in that the fuse array 230d further includes the fuse cell 235a including an anti-fuse element AF5 and a transistor 245. The anti-fuse element AF5 may represent the availability of a segment designated by the anti-fuse elements AF1, AF2, and AF3.

In other words, the anti-fuse element AF5 may represent the defective state of the segment designated by the anti-fuse elements AF1, AF2, and AF3. For example, if the anti-fuse element AF1 is programmed and the anti-fuse elements AF2 and AF4 are not programmed, so that a segment 3111b is designated, the anti-fuse element AF5 is programmed to represent that the segment 3111b is defective. In this case, a coding signal CS5 may have a logic level according to the program state of the anti-fuse element AF5.

FIG. 13 illustrates an example of coding the anti-fuse elements when the fuse array of FIG. 6 is configured as illustrated in FIG. 12. Referring to FIGS. 12 and 13, the anti-fuse elements AF1, AF2, and AF3 may be coded to output the coding signals CS1, CS2, and CS3 having one of logic levels of “000”, “100”, “110”, “010”, “001”, “101”, “011”, and “111” according to program states.

The anti-fuse element A4 may be coded to have a logic level of “0” or “1” according to the designation state of a segment adjacent to a segment designated through the coding of the anti-fuse elements AF1, AF2, and AF3. In addition, the anti-fuse element AF5 may represent the defective state of the segment designated through the coding of the anti-fuse elements AF1, AF2, and AF3. Therefore, according to the semiconductor memory device 10, the segment designated as being defective can be prevented from being substituted for the defective cell due to the anti-fuse element AF5.

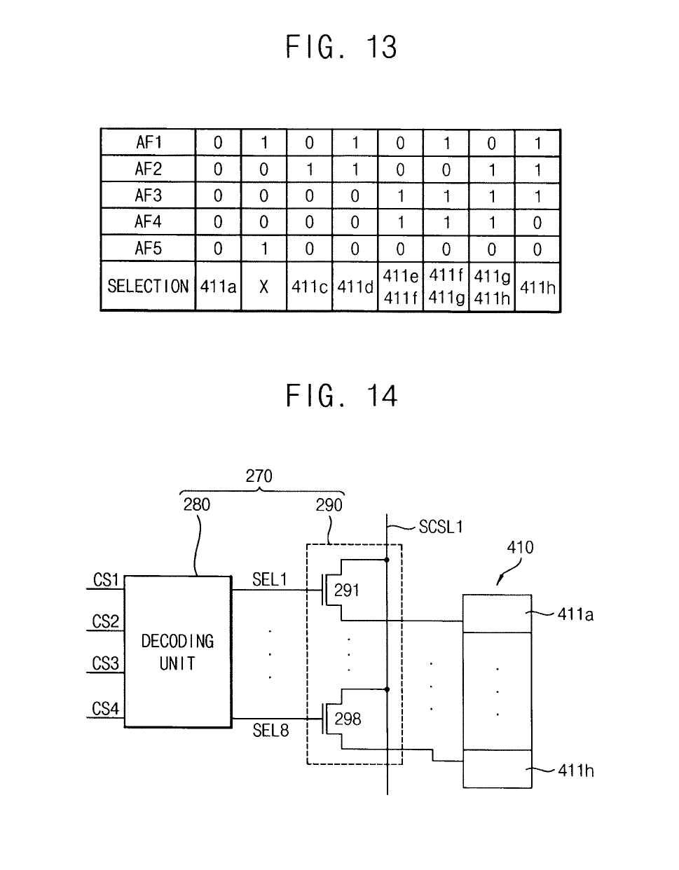

FIG. 14 illustrates an example of the decoder 270 of FIG. 6. Referring to FIG. 14, the decoder 270 may include a decoding unit 280 and a switching unit 290. The decoding unit 280 decodes the coding signals CS1 to CS3 (or CS1 to CS4) provided from the fuse array 230 to output a plurality of select signals SEL1 to SEL8. For example, the select signals SEL1 to SEL8 may have logic levels based on the logic levels of the coding signals CS1 to CS3.

The switching unit 290 may include a plurality of switches 291 to 298. Each of the switches 291 to 298 has a first electrode connected with the spare column select line SCSL1, a second electrode connected with each of the segments 411a to 411h, and a gate to receive the select signals SEL1 to SEL8. Among the select signals SEL1 to SEL8, select signals corresponding to a segment designated by the coding signals CS1 to CS3 may have high levels and remaining coding signals may have low levels. Accordingly, the switches 291 to 298 may connect at least one segment designated by the coding signals CS1 to CS4 with the spare column select line SCSL1 in response to the select signals SEL1 to SEL8.

For example, if the fuse elements included in the fuse array 230 are coded as illustrated in FIG. 8, and if the defective memory cell 3111b is substituted with the segment 411c, the select signals SEL1 to SEL8 obtained by decoding the coding signals CS1 to CS3 of “010” may be “00100000.” The switching unit 290 may connect the segment 411c with the spare column select line SCSL1 in response to the select signals SEL1 to SEL8 of “00100000. For example, if the fuse elements included in the fuse array 230 are coded as illustrated in FIG. 11, and if the coding signals CS1 to CS4 are “0011”, the decoded select signals SEL1 to SEL8 may be “00001100”. The switching unit 290 may connect the segments 411e and 411f with the spare column select line SCSL1 in response to the select signals SEL1 to SEL8 of “0001100”.

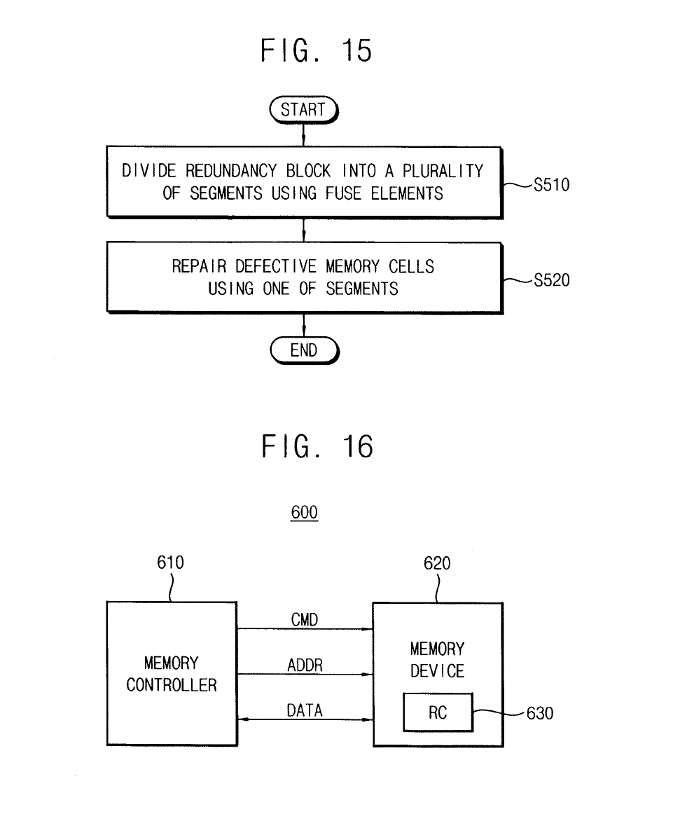

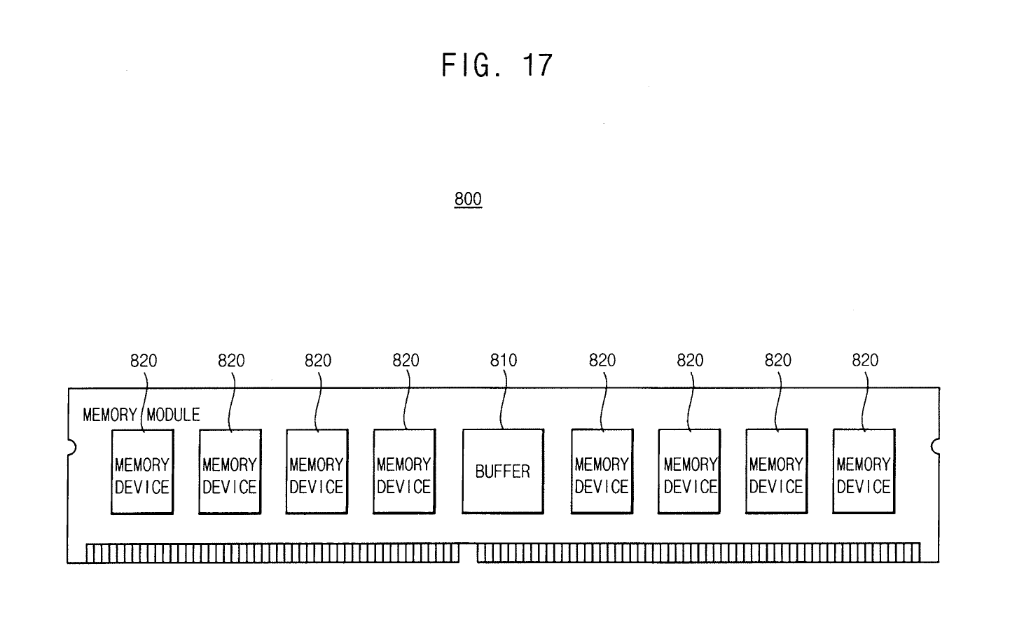

FIG. 15 illustrates an embodiment of a repair method of a semiconductor memory device. The repair method may be performed with reference to FIGS. 1 to 15.

The sub-redundancy block corresponding to the sub-memory block having the defective cell is partitioned into a plurality of segments by using the fuse elements of the fuse array 230 (block S510). The defective cell is substituted with at least one of the segments (block S520). If the address CADDi, which is currently input, is matched with one of the redundancy addresses RCAD1 to RCADk stored in the fuse circuit 210, the redundancy enable signal CRENi is activated.

The redundancy decoder 260 decodes the redundancy enable signal CRENi to activate the spare column select line SCSLi. The fuse array 230 outputs the coding signal CS, which designates at least one of the segments constituting the sub-redundancy block, to the decoder 270 in response to the activated redundancy enable signal CRENi. The decoder 270 decodes the coding signal CS to connect the segment designated by the coding signal CS with the spare column select line SCSLi, so that the defective cell is substituted with the segment.

FIG. 16 illustrates an embodiment of a memory system 600 which includes a memory controller 610 and a semiconductor memory device 620. The memory controller 610 may transfer a command CMD and an address ADDR to the semiconductor memory device 620 based on a request of a host. In addition, the memory controller 610 may input data DATA to the semiconductor memory device 620 based on the request of the host, or output the data DATA from the semiconductor memory device 620. In other words, the memory controller 610 may control the semiconductor memory device 620.

The semiconductor memory device 620 may employ the semiconductor memory device 10 of FIG. 1. Accordingly, the semiconductor memory device 620 may include a memory cell array including a normal cell array and a redundancy cell array, and a redundancy circuit 630 including a fuse circuit, a redundancy decoder, a fuse array, and decoder. In the semiconductor memory device 620, the redundancy block (sub-redundancy block) provided in the redundancy cell array is partitioned into a plurality of segments, and the segments may be coded in the fuse elements, which are provided in the fuse array, based on the availability states of the segments.

If the normal cell array includes a defective cell, at least one of the segments may be connected with the spare column select line based on a coding signal output from the fuse array in order to substitute the defective cell. Accordingly, the semiconductor memory device 620 can minimize the increase of the fuse elements while effectively using the redundancy resources.

The semiconductor memory device 620 may include a predetermined memory device to substitute the defective cell with the redundancy cell. The semiconductor memory device 620 may include a DRAM (Dynamic Random Access Memory) such as a DDR SDRAM (Double Data Rate Synchronous Dynamic Random Access Memory), a LPDDR (Low Power Double Data Rate) SDRAM, a GDDR (Graphics Double Data Rate) SDRAM, or an RDRAM (Rambus Dynamic Random Access Memory). In addition, the semiconductor memory device 620 may include a non-volatile memory device such as a Flash Memory, a PRAM (Phase Change Random Access Memory), an RRAM (Resistance Random Access Memory), an NFGM (Nano Floating Gate Memory), a PoRAM (Polymer Random Access Memory), an MRAM (Magnetic Random Access Memory), or an FRAM (Ferroelectric Random Access Memory).

FIG. 17 illustrates an embodiment of a memory module 800 which includes a plurality of semiconductor memory devices 820. In some embodiments, the memory module 800 may be an unbuffered dual in-line memory module (UDIMM), a registered dual in-line memory module (RDIMM), a fully buffered dual in-line memory module (FBDIMM), a load reduced dual in-line memory module LRDIMM, etc.

The memory module 800 may further a buffer 810 that provides a command/address signal and data by buffering the command/address signal and the data from a memory controller through a plurality of transmission lines. In some embodiments, data transmission lines between the buffer 810 and the semiconductor memory devices 820 may be coupled in a point-to-point topology, and command/address transmission lines between the buffer 810 and the semiconductor memory devices 820 may be coupled in a multi-drop topology, a daisy-chain topology, a fly-by daisy-chain topology, or the like. Since the buffer 810 buffers both the command/address signal and the data, the memory controller may interface with the memory module 800 by driving only a load of the buffer 810. Accordingly, the memory module 800 may include more memory devices and/or more memory ranks, and a memory system may include more memory modules.

Each of the semiconductor memory devices 810 may include the semiconductor memory device 10 of FIG. 1. Accordingly, the semiconductor memory device 820 may include a memory cell array including a normal cell array and a redundancy cell array, and a redundancy circuit including a fuse circuit, a redundancy decoder, a fuse array, and decoder. In the semiconductor memory device 820, the redundancy block (sub-redundancy block) provided in the redundancy cell array is partitioned into a plurality of segments, and the segments may be coded in the fuse elements, which are provided in the fuse array, based on the availability states of the segments. If the normal cell array includes a defective cell, at least one of the segments may be connected with the spare column select line based on a coding signal output from the fuse array in order to substitute the defective cell. Accordingly, the semiconductor memory device 820 can minimize the increase of the fuse elements while effectively using the redundancy resources.

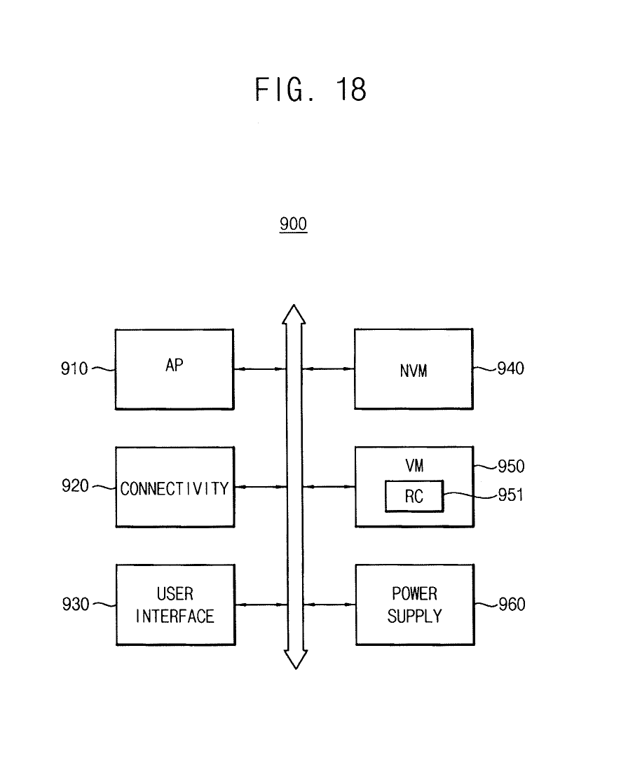

FIG. 18 illustrates an embodiment of a mobile system 900 which includes an application processor 910, a connectivity unit 920, a semiconductor memory device 950, a nonvolatile memory device 940, a user interface 930 and a power supply 960. In some embodiments, the mobile system 900 may be a mobile phone, a smart phone, a personal digital assistant (PDA), a portable multimedia player (PMP), a digital camera, a music player, a portable game console, a navigation system, etc.

The application processor 910 may execute applications, such as a web browser, a game application, a video player, etc. In some embodiments, the application processor 910 may include a single core or multiple cores. For example, the application processor 910 may be a multi-core processor, such as a dual-core processor, a quad-core processor, a hexa-core processor, etc. The application processor 910 may include an internal or external cache memory.

The connectivity unit 920 may perform wired or wireless communication with an external device. For example, the connectivity unit 920 may perform Ethernet communication, near field communication (NFC), radio frequency identification (RFID) communication, mobile telecommunication, memory card communication, universal serial bus (USB) communication, etc. In some embodiments, connectivity unit 920 may include a baseband chipset that supports communications, such as global system for mobile communications (GSM), general packet radio service (GPRS), wideband code division multiple access (WCDMA), high speed downlink/uplink packet access (HSxPA), etc.

The semiconductor memory device 950 may store data processed by the application processor 910, or may operate as a working memory. For example, the semiconductor memory device 950 may be a dynamic random access memory, such as DDR SDRAM, LPDDR SDRAM, GDDR SDRAM, RDRAM, etc., or may be any volatile memory device that requires a refresh operation. The semiconductor memory device 950 may include the semiconductor memory device 10 of FIG. 1.

Accordingly, the semiconductor memory device 950 may include a memory cell array including a normal cell array and a redundancy cell array, and a redundancy circuit 951 including a fuse circuit, a redundancy decoder, a fuse array, and decoder. In the semiconductor memory device 950, the redundancy block (sub-redundancy block) provided in the redundancy cell array is partitioned into a plurality of segments, and the segments may be coded in the fuse elements, which are provided in the fuse array, based on the availability states of the segments. If the normal cell array includes a defective cell, at least one of the segments may be connected with the spare column select line based on a coding signal output from the fuse array in order to substitute the defective cell. Accordingly, the semiconductor memory device 950 can minimize the increase of the fuse elements while effectively using the redundancy resources.

The nonvolatile memory device 940 may store a boot image for booting the mobile system 900. For example, the nonvolatile memory device 940 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 930 may include at least one input device, such as a keypad, a touch screen, etc., and at least one output device, such as a speaker, a display device, etc. The power supply 960 may supply a power supply voltage to the mobile system 900. In some embodiments, the mobile system 900 may further include a camera image processor (CIS), and/or a storage device, such as a memory card, a solid state drive (SSD), a hard disk drive (HDD), a CD-ROM, etc.

In some embodiments, the mobile system 900 and/or components of the mobile system 900 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

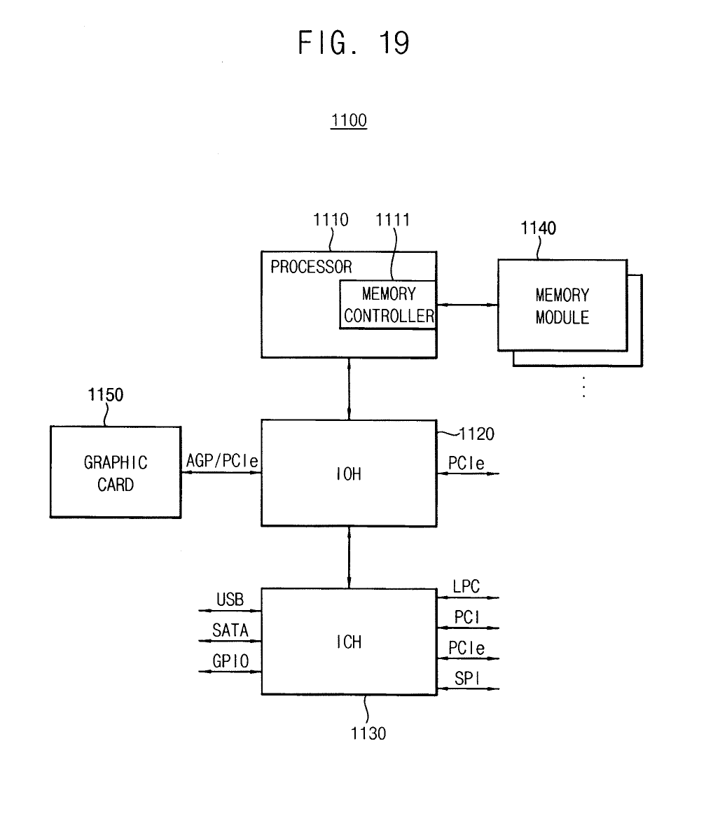

FIG. 19 illustrates an embodiment of a computing system 1100 which includes a processor 1110, an input/output hub (IOH) 1120, an input/output controller hub (ICH) 1130, at least one memory module 1140 and a graphics card 1150. In some embodiments, the computing system 1100 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 1110 may perform various computing functions, such as executing specific software for performing specific calculations or tasks. For example, the processor 1110 may be a microprocessor, a central process unit (CPU), a digital signal processor, or the like. In some embodiments, the processor 1110 may include a single core or multiple cores. For example, the processor 1110 may be a multi-core processor, such as a dual-core processor, a quad-core processor, a hexa-core processor, etc. Although FIG. 28 illustrates the computing system 1100 including one processor 1110, in some embodiments, the computing system 1100 may include a plurality of processors. The processor 1110 may include an internal or external cache memory.

The processor 1110 may include a memory controller 1111 for controlling operations of the memory module 1140. The memory controller 1111 included in the processor 1110 may be referred to as an integrated memory controller (IMC). The memory controller 1111 may include structure and/or perform the methods of one or more of the embodiments described herein.

A memory interface between the memory controller 1111 and the memory module 1140 may be implemented with a single channel including a plurality of signal lines, or may bay be implemented with multiple channels, to each of which at least one memory module 1140 may be coupled. In some embodiments, the memory controller 1111 may be located inside the input/output hub 1120, which may be referred to as memory controller hub (MCH).

The memory module 1140 may include a plurality of semiconductor memory devices that store data provided from the memory controller 1111. Each of the semiconductor memory devices may include the semiconductor memory device 10 of FIG. 1. Accordingly, the semiconductor memory device may include a memory cell array including a normal cell array and a redundancy cell array, and a redundancy circuit including a fuse circuit, a redundancy decoder, a fuse array, and decoder. In the semiconductor memory device, the redundancy block (sub-redundancy block) provided in the redundancy cell array is partitioned into a plurality of segments, and the segments may be coded in the fuse elements, which are provided in the fuse array, based on the availability states of the segments. If the normal cell array includes a defective cell, at least one of the segments may be connected with the spare column select line based on a coding signal output from the fuse array in order to substitute the defective cell. Accordingly, the semiconductor memory device can minimize the increase of the fuse elements while effectively using the redundancy resources.

The input/output hub 1120 may manage data transfer between processor 1110 and devices, such as the graphics card 1150. The input/output hub 1120 may be coupled to the processor 1110 via various interfaces. For example, the interface between the processor 1110 and the input/output hub 1120 may be a front side bus (FSB), a system bus, a HyperTransport, a lightning data transport (LDT), a QuickPath interconnect (QPI), a common system interface (CSI), etc. Although FIG. 40 illustrates the computing system 1100 including one input/output hub 1120, in some embodiments, the computing system 1100 may include a plurality of input/output hubs. The input/output hub 1120 may provide various interfaces with the devices. For example, the input/output hub 1120 may provide an accelerated graphics port (AGP) interface, a peripheral component interface-express (PCIe), a communications streaming architecture (CSA) interface, etc.

The graphics card 1150 may be coupled to the input/output hub 1120 via AGP or PCIe. The graphics card 1150 may control a display device (not shown) for displaying an image. The graphics card 1150 may include an internal processor for processing image data and an internal memory device. In some embodiments, the input/output hub 1120 may include an internal graphics device along with or instead of the graphics card 1150 outside the graphics card 1150. The graphics device included in the input/output hub 1120 may be referred to as integrated graphics. Further, the input/output hub 1120 including the internal memory controller and the internal graphics device may be referred to as a graphics and memory controller hub (GMCH).

The input/output controller hub 1130 may perform data buffering and interface arbitration to efficiently operate various system interfaces. The input/output controller hub 1130 may be coupled to the input/output hub 1120 via an internal bus, such as a direct media interface (DMI), a hub interface, an enterprise Southbridge interface (ESI), PCIe, etc. The input/output controller hub 1130 may provide various interfaces with peripheral devices. For example, the input/output controller hub 1130 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 1110, the input/output hub 1120 and the input/output controller hub 1130 may be implemented as separate chipsets or separate integrated circuits. In other embodiments, at least two of the processor 1110, the input/output hub 1120 and the input/output controller hub 1130 may be implemented as a single chipset.

By way of summation and review, in accordance with one or more embodiments a semiconductor memory device is provided with a redundancy block (or the sub-redundancy block) in an redundancy cell array which may be partitioned into a plurality of segments. The segments may be coded in fuse elements provided in the fuse array based on the availability states of the segments. If a normal cell array includes a defective cell, at least one of the segments may be connected with the spare column select line based on a coding signal output from the fuse array. The at least one segment may therefore be used as a substitute for the defective cell. Accordingly, the semiconductor memory device can prevent an increase in the number of fuse elements used, while simultaneously effectively using redundancy resources. One or more embodiments are also useful in memory devices and memory systems.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A redundancy circuit, comprising:
a redundancy decoder configured to decode a redundancy enable signal generated when an address of a defective cell matches an input address, the decoded redundancy enable signal to activate a spare column select line connected with a redundancy block to be substituted for the defective cell designated by the defective cell address;
a fuse array including a plurality of fuse elements to designate a plurality of segments in the redundancy block based on availability of the segments; and
a decoder configured to decode a plurality of coding signals provided from the fuse array and configured to connect at least one of the fuse elements with the spare column select line.

2. The redundancy circuit as claimed in claim 1, wherein the fuse array provides the coding signals to the decoder in response to the redundancy enable signal.

3. The redundancy circuit as claimed in claim 2, wherein the fuse array comprises a plurality of transistors connected with the fuse elements, respectively, to provide coding information of the fuse elements to the decoder as the coding signals in response to the redundancy enable signal.

4. The redundancy circuit as claimed in claim 1, wherein each of the fuse elements includes an anti-fuse element.

5. The redundancy circuit as claimed in claim 4, wherein the anti-fuse element outputs a high-level coding signal when the anti-fuse element is programmed, and outputs a low-level coding signal when the anti-fuse element is not programmed.

6. The redundancy circuit as claimed in claim 1, wherein each of the fuse elements includes an electrical fuse element.

7. The redundancy circuit as claimed in claim 6, wherein the electrical fuse element outputs a low-level coding signal when the electrical fuse element is programmed, and outputs a high-level coding signal when the electrical fuse element is not programmed.

8. The redundancy circuit as claimed in claim 1, wherein:
all fuse elements except for at least one fuse element are used to designate corresponding ones of the segments, and
the at least one fuse element is indicative of a designation state of a segment adjacent to one of the segments designated by remaining ones of the fuse elements.

9. The redundancy circuit as claimed in claim 1, wherein:
all fuse elements except for at least first and second fuse elements designate corresponding segments,
the first fuse element represents an availability state of one segment designated by the remaining ones of the fuse elements, and
the second fuse element represents a designation state of a segment adjacent to the one segment designated by the remaining ones of the fuse elements.

10. The redundancy circuit as claimed in claim 1, wherein the redundancy decoder deactivates a normal column decoder to access the defective cell designated by the input address, in response to the redundancy enable signal.

11. The redundancy circuit as claimed in claim 1, wherein the decoder comprises:
a decoding unit to decode the coding signals to provide a plurality of select signals; and
a switching unit comprising a plurality of switches to selectively connect the segments with the spare column select line in response to the select signals.

12. A semiconductor memory device, comprising:
a memory cell array including normal memory cell blocks and redundancy cell blocks corresponding to the normal memory cell blocks;
a normal decoder configured to access the normal memory cell blocks in response to an input address; and
a redundancy circuit configured to substitute a defective cell, in at least one of the normal memory cell blocks, with a segment of the redundancy cell blocks, wherein the redundancy circuit comprises:
a redundancy decoder configured to decode a redundancy enable signal generated when an address of a defective cell matches an input address, the decoded redundancy enable signal to activate a spare column select line connected with a redundancy block to be substituted for the defective cell designated by the defective cell address;
a fuse array including a plurality of fuse elements to designate a plurality of segments in the redundancy block based on availability of the segments; and
a decoder configured to decode a plurality of coding signals provided from the fuse array and configured to connect at least one of the fuse elements with the spare column select line.

13. The semiconductor memory device as claimed in claim 12, wherein:
the redundancy decoder deactivates the normal decoder in response to the redundancy enable signal, and
the fuse array includes a plurality of transistors connected with the fuse elements, respectively, to provide coding information of the fuse elements to the decoder as the coding signals in response to the redundancy enable signal.

14. The semiconductor memory device as claimed in claim 13, wherein:
all fuse elements except for at least one fuse element designate corresponding ones of the segments, and
the at least one fuse element is indicative of a designation state of a segment adjacent to one segment designated by remaining ones of the fuse elements.

15. The semiconductor memory device as claimed in claim 12, wherein the redundancy block is selected by a portion of bits of a row address constituting the input address to access the memory cell array.

16. The semiconductor memory device as claimed in claim 12, further comprising a fuse circuit configured to selectively activate the redundancy enable signal based on a match between the address of the defective cell and the input address.

17. A controller, comprising:
a first circuit to receive a signal indicative of a defective cell in a first array of memory locations, the defective cell included in a sub-block of the first array of memory locations; and
a second circuit to generate a signal to substitute the defective cell in the sub-block of the first array of memory locations with a segment in a second array of memory locations, the segment in the second array of memory locations included in a sub-block of the second array of memory locations, wherein cells in the sub-block of the first array of memory locations except the defective cell and the segment in the second array of memory locations form a single storage location for storing different bits of data.

18. The controller as claimed in claim 17, wherein the defective cell in the sub-block of the first array of memory locations and the segment in the second array of memory locations have a same size.

19. The controller as claimed in claim 17, wherein the sub-block in the second array of memory locations includes a plurality of segments in one-to-one correspondence with cells in the sub-block of the first array of memory locations.

20. The controller of claim 19, wherein the second circuit is to generate the signal to substitute the defective cell in the sub-block of the first array of memory locations with the segment in the sub-block of the second array of memory locations based on availability states of the segments in the sub-block of the second array of memory locations.
